(19) United States
(12) Patent Application Publication
(10) Pub. No.: US 2026/0171044 A1
(43) Pub. Date: Jun. 18, 2026

(54) SCANNING SIGNAL LINE DRIVE CIRCUIT AND DISPLAY DEVICE

(71) Applicant: Sharp Display Technology Corporation, Kameyama City (JP)

(72) Inventor: Yoshihisa TAKAHASHI, Kameyama City (JP)

(21) Appl. No.: 19/411,732

(22) Filed: Dec. 8, 2025

(30) Foreign Application Priority Data
Dec. 13, 2024 (JP) 2024-218629

(51) Int. Cl. G09G 3/36; G11C 19/28

(52) U.S. Cl. CPC G09G 3/3677; G11C 19/28; G09G 2300/0408; G09G 2310/0286

(57) ABSTRACT

Each stage of a shift register circuit of a scanning signal line drive circuit includes 1st, 2nd, and 3rd transistors, and a stabilization circuit that suppresses fluctuations in potentials of a first internal node and a first output terminal during a non-select period. The stabilization circuit includes at least one of a 4th transistor including a gate electrically connected to a second internal node, and a source and a drain, one of the source and the drain electrically connected to the first internal node and another of the source and the drain configured to be supplied with a first reference potential, and a 5th transistor including a gate electrically connected to the second internal node, and a source and a drain, one of the source and the drain electrically connected to the first output terminal and another of the source and the drain configured to be supplied with a second reference potential. During at least part of a vertical blanking period, a potential of the second internal node is lower than a potential of the first internal node, a potential of the first output terminal, the first reference potential, and the second reference potential.

### CROSS-REFERENCE TO RELATED APPLICATIONS

This application claims the benefit of priority to Japanese Patent Application Number 2024-218629 filed on Dec. 13, 2024. The entire contents of the above-identified application are hereby incorporated by reference.

### BACKGROUND

### Technical Field

The disclosure relates to a scanning signal line drive circuit and a display device.

In some cases, peripheral circuits such as drive circuits are monolithically (integrally) formed in a non-display region (sometimes referred to as a peripheral region) of an active matrix substrate provided in a display device. By forming the peripheral circuits monolithically, the non-display region can be narrowed (frame narrowing) and the mounting process can be simplified, resulting in cost reduction. For example, in the non-display region, a scanning signal line drive circuit may be monolithically formed, and a display signal line drive circuit may be mounted using a chip on glass (COG) method. The monolithically formed scanning signal line drive circuit is referred to as a gate driver monolithic (GDM) circuit or a gate on array (GOA) circuit.

The scanning signal line drive circuit outputs scanning signals to multiple scanning signal lines so that these scanning signal lines are selected sequentially during vertical scanning periods. Therefore, the scanning signal line drive circuit includes a shift register circuit including multiple stages corresponding to the number of scanning signal lines. Each stage of the shift register circuit is a circuit that includes multiple thin film transistors (TFTs) (sometimes referred to as a “unit circuit”). The unit circuit includes TFTs that are electrically connected to an output terminal and control the output of scanning signals to the scanning wiring lines (sometimes referred to as “output elements”).

In each stage of the shift register circuit, it is preferable that the scanning signal output be reliably maintained as a low level during a period when the corresponding scanning signal line is not selected (referred to as a “non-select period”). Therefore, it has been proposed to provide a stabilization circuit in each stage of the shift register circuit to more reliably maintain the scanning signal output during the non-select period at a low level. Such a stabilization circuit is disclosed, for example, in WO 2017/006815.

### SUMMARY

However, among TFTs included in the stabilization circuit, TFTs that operate during the non-select period (hereinafter also referred to as “stabilization elements”) have a high operation duty, and thus characteristics thereof deteriorate quickly. Therefore, there is a concern that an effect of the stabilization circuit may become insufficient due to ongoing deterioration of the stabilization element's characteristics. Further, different deterioration rates of the stabilization elements and the output elements may disrupt balance in circuit operation. For example, there is a concern that while the stabilization element may deteriorate and generate minute noise, the output element that has sufficient performance may pick up this minute noise and malfunction.

Embodiments of the disclosure have been made in view of the above problems, and an object thereof is to provide a scanning signal line drive circuit capable of suppressing deterioration of characteristics of stabilization elements of a stabilization circuit provided in each stage of a shift register circuit.

This specification discloses a scanning signal line drive circuit and a display device described in the following items.

### Item 1

A scanning signal line drive circuit configured to supply scanning signals to multiple scanning signal lines included in a display device, the scanning signal line drive circuit including a shift register circuit including multiple stages, in which each of the multiple stages includes a first clock terminal configured to receive a first clock signal, a set terminal configured to receive a set signal, a reset terminal configured to receive a reset signal, a first output terminal configured to output a scanning signal, a 1st transistor including a gate electrically connected to a first internal node, and a source and a drain, one of the source and the drain electrically connected to the clock terminal and another of the source and the drain electrically connected to the first output terminal, a 2nd transistor including a gate electrically connected to the set terminal, and a source and a drain, one of the source and the drain electrically connected to the first internal node, a 3rd transistor including a gate electrically connected to the reset terminal, and a source and a drain, one of the source and the drain electrically connected to the first internal node and another of the source and the drain electrically connected to a first reference voltage source, a stabilization circuit electrically connected to the first internal node and the first output terminal, and configured to suppress fluctuations in potentials of the first internal node and the first output terminal during a non-select period, the stabilization circuit includes at least one of a 4th transistor including a gate electrically connected to a second internal node, and a source and a drain, one of the source and the drain electrically connected to the first internal node, and another of the source and the drain supplied with a first reference potential, and a 5th transistor including a gate electrically connected to the second internal node, and a source and a drain, one of the source and the drain electrically connected to the first output terminal and another of the source and the drain configured to be supplied with a second reference potential, the second reference potential being identical to or different from the first reference potential, and during at least part of a vertical blanking period of an effective display period and the vertical blanking period included in a vertical scanning period, a potential of the second internal node is lower than a potential of the first internal node, a potential of the first output terminal, the first reference potential, and the second reference potential.

### Item 2

The scanning signal line drive circuit according to item 1, in which the stabilization circuit includes at least the 4th transistor of the 4th transistor and the 5th transistor, the other of the source and the drain of the 4th transistor is electrically connected to the first reference voltage source, the stabilization circuit further includes a 6th transistor including a gate electrically connected to the first internal node, and a source and a drain, one of the source and the drain electrically connected to the second internal node and another of the source and the drain electrically connected to a second reference voltage source, and a potential of the second reference voltage source is practically identical to a potential of the first reference voltage source during the effective display period, and is lower than the potential of the first reference voltage source during the at least part of the vertical blanking period.

### Item 3

The scanning signal line drive circuit according to item 2, in which the stabilization circuit further includes a 7th transistor including a source and a drain, one of the source and the drain electrically connected to a first charge supply source configured to supply charge to the second internal node and another of the source and the drain electrically connected to the second internal node, and a potential of the first charge supply source is lower than the potential of the first reference voltage source during the at least part of the vertical blanking period.

### Item 4

The scanning signal line drive circuit according to item 2 or 3, in which the stabilization circuit further includes an 8th transistor including a gate electrically connected to the set terminal, and a source and a drain, one of the source and the drain electrically connected to the second internal node and another of the source and the drain electrically connected to the second reference voltage source.

### Item 5

The scanning signal line drive circuit according to any one of items 1 to 4, in which each of the multiple stages further includes a second output terminal configured to output a signal configured to drive another stage at the same timing as the scanning signal is output from the first output terminal, and a 9th transistor including a gate electrically connected to the first internal node, and a source and a drain, one of the source and the drain electrically connected to the clock terminal and another of the source and the drain electrically connected to the second output terminal.

### Item 6

The scanning signal line drive circuit according to item 5, in which each of the multiple stages further includes a 10th transistor including a gate electrically connected to the second internal node, and a source and a drain, one of the source and the drain electrically connected to the second output terminal and another of the source and the drain electrically connected to the first reference voltage source.

### Item 7

The scanning signal line drive circuit according to any one of items 1 to 6, in which each of the multiple stages further includes an 11th transistor including a gate configured to be supplied with a signal output from another stage, and a source and a drain, one of the source and the drain electrically connected to the first output terminal and another of the source and the drain electrically connected to the first reference voltage source.

### Item 8

The scanning signal line drive circuit according to item 5, in which the stabilization circuit includes at least the 5th transistor of the 4th transistor and the 5th transistor, each of the multiple stages further includes a 10th transistor including a gate electrically connected to the second internal node, and a source and a drain, one of the source and the drain electrically connected to the second output terminal and another of the source and the drain electrically connected to the first reference voltage source, the other of the source and the drain of the 5th transistor is electrically connected to a third reference voltage source, and a potential of the third reference voltage source is higher than a potential of the first reference voltage source.

### Item 9

The scanning signal line drive circuit according to item 8, in which each of the multiple stages further includes an 11th transistor including a gate configured to be supplied with a signal output from another stage, and a source and a drain, one of the source and the drain electrically connected to the first output terminal and another of the source and the drain electrically connected to the third reference voltage source.

### Item 10

The scanning signal line drive circuit according to any one of items 1 to 9, in which the stabilization circuit includes both the 4th transistor and the 5th transistor, and the other of the source and the drain of the 4th transistor and the other of the source and the drain of the 5th transistor are each electrically connected to the first reference voltage source, and the first reference potential is identical to the second reference potential.

### Item 11

The scanning signal line drive circuit according to item 2, in which each of the multiple stages further includes a second clock terminal configured to receive a second clock signal having a phase identical to or a phase shifted from a phase of the first clock signal, and a third clock terminal configured to receive a third clock signal having a phase shifted from the phase of the second clock signal, and the stabilization circuit further includes a 12th transistor including a gate electrically connected to the second clock terminal and a source and a drain, one of the source and the drain electrically connected to the second internal node, and a 13th transistor including a gate electrically connected to the third clock terminal, and a source and a drain, one of the source and the drain electrically connected to the second internal node and another of the source and the drain electrically connected to the second reference voltage source.

### Item 12

The scanning signal line drive circuit according to item 3, in which the stabilization circuit further includes a 14th transistor including a gate electrically connected to a third internal node, and a source and a drain, one of the source and the drain electrically connected to the first internal node and another of the source and the drain configured to be supplied with the first reference potential, a 15th transistor including a gate electrically connected to the third internal node, and a source and a drain, one of the source and the drain electrically connected to the first output terminal and another of the source and the drain configured to be supplied with the second reference potential, a 16th transistor including a gate electrically connected to the first internal node, and a source and a drain, one of the source and the drain electrically connected to the third internal node and another of the source and the drain electrically connected to the second reference voltage source, and a 17th transistor including a source and a drain, one of the source and the drain electrically connected to a second charge supply source configured to supply charge to the third internal node and another of the source and the drain electrically connected to the third internal node, a potential of the second charge supply source is lower than the potential of the first reference voltage source during the at least part of the vertical blanking period, and the potential of the first charge supply source is higher than the potential of the second charge supply source during the effective display period of one of two consecutive vertical scanning periods, and the potential of the second charge supply source is higher than the potential of the first charge supply source during the effective display period of another of the two consecutive vertical scanning periods.

### Item 13

The scanning signal line drive circuit according to item 3, in which the stabilization circuit further includes a 14th transistor including a gate electrically connected to a third internal node, and a source and a drain, one of the source and the drain electrically connected to the first internal node and another of the source and the drain configured to be supplied with the first reference potential, a 15th transistor including a gate electrically connected to the third internal node, and a source and a drain, one of the source and the drain electrically connected to the first output terminal and another of the source and the drain configured to be supplied with the second reference potential, an 18th transistor including a source and a drain, one of the source and the drain electrically connected to a first charge supply source configured to supply charge to the second internal node and another of the source and the drain electrically connected to the second internal node, a 19th transistor including a gate, a source, and a drain, the gate and one of the source and the drain electrically connected to the second internal node and another of the source and the drain electrically connected to the first charge supply source, a 20th transistor including a source and a drain, one of the source and the drain electrically connected to a second charge supply source configured to supply charge to the third internal node and another of the source and the drain electrically connected to the third internal node, a 21st transistor including a gate, a source, and a drain, the gate and one of the source and the drain electrically connected to the third internal node and another of the source and the drain electrically connected to the second charge supply source, a 22nd transistor including a gate electrically connected to the first internal node, and a source and a drain, one of the source and the drain electrically connected to the second internal node and another of the source and the drain electrically connected to the third internal node, and a 23rd transistor including a gate electrically connected to the set terminal, and a source and a drain, one of the source and the drain electrically connected to the second internal node and another of the source and the drain electrically connected to the third internal node, the potential of the first charge supply source and a potential of the second charge supply source are each lower than the potential of the first reference voltage source during the at least part of the vertical blanking period, and during the effective display period of one of two consecutive vertical scanning periods, the potential of the first charge supply source is higher than the potential of the second charge supply source, and during the effective display period of another of the two consecutive vertical scanning periods, the potential of the second charge supply source is higher than the potential of the first charge supply source.

### Item 14

A display device having multiple pixels arranged in a matrix including multiple pixel rows and multiple pixel columns, the display device including multiple scanning signal lines, each of the multiple scanning signal lines being associated with one of the multiple pixel rows, and the scanning signal line drive circuit according to any one of items 1 to 13 configured to supply scanning signals to the multiple scanning signal lines.

According to the embodiments of the disclosure, a scanning signal line drive circuit can be provided that can suppress deterioration of characteristics of stabilization elements in a stabilization circuit provided in each stage of a shift register circuit.

### BRIEF DESCRIPTION OF DRAWINGS

The disclosure will be described with reference to the accompanying drawings, wherein like numbers reference like elements.

FIG. 1 is a schematic plan view illustrating a liquid crystal display device 100 according to an embodiment of the disclosure.

FIG. 2 is a diagram illustrating a circuit configuration for outputting scanning signals.

FIG. 3 is a circuit diagram illustrating a configuration example of each stage of a shift register circuit SR.

FIG. 4 is an example of a timing chart illustrating an operation of the shift register circuit SR.

FIG. 5 is a circuit diagram illustrating another example of a shift register circuit (shift register circuit SRA).

FIG. 6 is a circuit diagram illustrating still another example of a shift register circuit (shift register circuit SRB).

FIG. 7 is an example of a timing chart illustrating an operation of the shift register circuit SRB.

FIG. 8 is a circuit diagram illustrating yet another example of a shift register circuit (shift register circuit SRC).

FIG. 9 is an example of a timing chart illustrating an operation of the shift register circuit SRC.

FIG. 10 is a circuit diagram illustrating a further example of a shift register circuit (shift register circuit SRD).

FIG. 11 is an example of a timing chart illustrating an operation of the shift register circuit SRD.

FIG. 12 is a circuit diagram illustrating a still further example of a shift register circuit (shift register circuit SRE).

FIG. 13 is an example of a timing chart illustrating an operation of the shift register circuit SRE.

FIG. 14 is a circuit diagram illustrating a yet further example of a shift register circuit (shift register circuit SRF).

FIG. 15 is an example of a timing chart illustrating an operation of the shift register circuit SRF.

### DESCRIPTION OF EMBODIMENTS

A scanning signal line drive circuit according to an embodiment of the disclosure is a scanning signal line drive circuit that supplies scanning signals to multiple scanning signal lines included in a display device, and includes a shift register circuit including multiple stages. Each of the multiple stages includes a first clock terminal configured to receive a first clock signal, a set terminal configured to receive a set signal, a reset terminal configured to receive a reset signal, a first output terminal configured to output a scanning signal, a 1st transistor including a gate electrically connected to a first internal node, and a source and a drain, one of the source and the drain electrically connected to the clock terminal and another of the source and the drain electrically connected to the first output terminal, a 2nd transistor including a gate electrically connected to the set terminal, and a source and a drain, one of the source and the drain electrically connected to the first internal node, a 3rd transistor including a gate electrically connected to the reset terminal, and a source and a drain, one of the source and the drain electrically connected to the first internal node and another of the source and the drain electrically connected to a first reference voltage source, a stabilization circuit electrically connected to the first internal node and the first output terminal, and configured to suppress fluctuations in potentials of the first internal node and the first output terminal during a non-select period. The stabilization circuit includes at least one of a 4th transistor including a gate electrically connected to a second internal node, and a source and a drain, one of the source and the drain electrically connected to the first internal node, and another of the source and the drain supplied with a first reference potential, and a 5th transistor including a gate electrically connected to the second internal node, and a source and a drain, one of the source and the drain electrically connected to the first output terminal and another of the source and the drain configured to be supplied with a second reference potential, the second reference potential being identical to or different from the first reference potential, and during at least part of a vertical blanking period of an effective display period and the vertical blanking period included in a vertical scanning period, a potential of the second internal node is lower than the potential of the first internal node, the potential of the first output terminal, the first reference potential, and the second reference potential.

Transistors included in each stage of the shift register circuit are switching elements, and a typical example of such elements is a TFT. The scanning signal line drive circuit according to the embodiment of the disclosure is a GOA circuit, and includes TFTs of a single polarity (i.e., n-type or p-type). The following description uses a GOA circuit including n-type TFTs as an example. Note that the electrical connections of a source and a drain of a p-type TFT are reversed from the electrical connections of a source and a drain of an n-type TFT.

As a clock signal, for example, a multi-phase clock signal such as a four-phase, six-phase, or eight-phase clock signal is used. A scanning signal output from a stage of the shift register circuit can be input to circuits of other stages as a set signal or a reset signal.

Hereinafter, embodiments of the disclosure will be described with reference to the accompanying drawings. Note that a liquid crystal display device will be described below as an example of a display device according to the embodiments of the disclosure. However, the display device according to the embodiments of the disclosure is not limited to a liquid crystal display device.

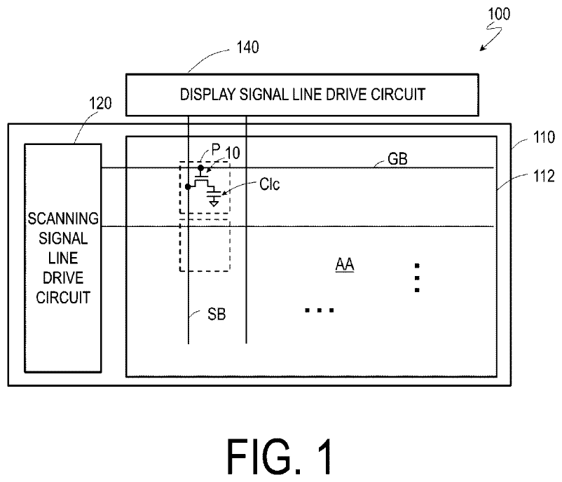

First, with reference to FIG. 1, an overall configuration of a liquid crystal display device 100 according to the embodiment of the disclosure will be described. FIG. 1 is a schematic plan view illustrating the liquid crystal display device 100.

As illustrated in FIG. 1, the liquid crystal display device 100 has multiple pixels P arranged in a matrix including multiple pixel rows and multiple pixel columns. The liquid crystal display device 100 is an active matrix liquid crystal display device, and includes a thin film transistor (TFT) 10 and a liquid crystal capacitance Clc for each pixel P. The pixel P may further include an auxiliary capacity Cs (not illustrated) electrically connected in parallel with the liquid crystal capacitance Clc. Herein, a description of the auxiliary capacity Cs is omitted. The liquid crystal capacitance Clc is constituted by, for example, a pixel electrode (not illustrated) formed on an active matrix substrate 110 and a common electrode (also referred to as a counter electrode; not illustrated) disposed to face the pixel electrode with a liquid crystal layer (not illustrated) interposed therebetween. The common electrode is formed, for example, on a counter substrate 112 placed to face the active matrix substrate 110. An area AA in which the multiple pixels P are arranged is referred to as an “active area” or a “display region”.

The liquid crystal display device 100 further includes multiple scanning signal lines (also referred to as “gate bus lines”) GB, each of which is associated with one of the multiple pixel rows, and multiple display signal lines (also referred to as “source bus lines”) SB, each of which is associated with one of the multiple pixel columns. A gate electrode of the TFT 10 of each pixel P is electrically connected to the scanning signal line GB associated with the pixel row including this pixel, and a source electrode of the TFT 10 of each pixel P is electrically connected to the display signal line SB associated with the pixel column including this pixel.

The liquid crystal display device 100 further includes a scanning signal line drive circuit (hereinafter also referred to as a “gate drive circuit”) 120 that supplies scanning signals to the multiple scanning signal lines GB, and a display signal line drive circuit (hereinafter also referred to as a “source drive circuit”) 140 that supplies display signals to the multiple display signal lines SB.

The gate drive circuit 120 is a GOA circuit, and is formed on the active matrix substrate 110 together with the pixel electrodes, the TFTs 10, the scanning signal lines GB, the display signal lines SB, and the like. As is well known, the active matrix substrate 110 can be fabricated, for example, by depositing a conductive layer (metal layer), a semiconductor layer, an insulating layer, and the like on a glass substrate and patterning these layers using known methods. The source drive circuit 140 may be, for example, a source driver IC mounted on the active matrix substrate 110, or may be a source driver IC mounted on a flexible substrate connected to the active matrix substrate 110.

The gate drive circuit 120 and the source drive circuit 140 are controlled by a control circuit (not illustrated). The control circuit includes a display control circuit including a timing controller and a power source circuit. The display control circuit supplies necessary control signals to the gate drive circuit 120 and the source drive circuit 140, and the power source circuit supplies necessary power supply voltages to the gate drive circuit 120 and the source drive circuit 140. Since the configuration and operation of the control circuit are well known, a detailed description thereof will be omitted.

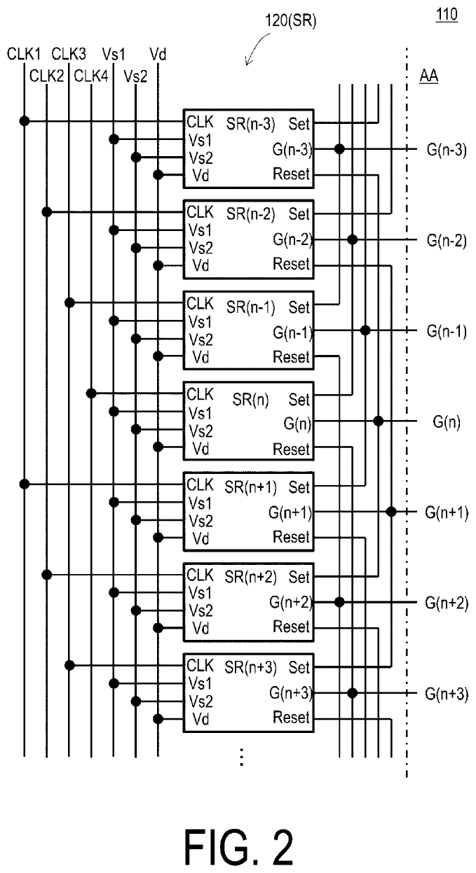

Next, a configuration of the gate drive circuit 120 will be described with reference to FIG. 2. FIG. 2 is a diagram illustrating a circuit configuration for outputting scanning signals. As illustrated in FIG. 2, the gate drive circuit 120 includes a shift register circuit SR, and the shift register circuit SR includes multiple stages (sometimes referred to as “unit circuits”). A scanning signal G is output from each stage of the shift register circuit SR to a corresponding scanning signal line GB. In FIG. 2, a scanning signal corresponding to an n-th pixel row is denoted by G(n), and an n-th stage of the shift register circuit SR is denoted by SR(n).

Each stage of the shift register circuit SR includes, as input terminals, a clock terminal CLK, a set terminal Set, a reset terminal Reset, a first reference voltage terminal Vs1, a second reference voltage terminal Vs2, and a charge supply terminal Vd. In this specification, for convenience of description, the same reference symbol may be used for a terminal and a signal input to or output from the terminal. Each stage of the shift register circuit SR includes an output terminal G as an output terminal.

A clock signal CLK is input to the clock terminal CLK. In the illustrated example, the clock signal CLK is a four-phase clock signal CLK1, CLK2, CLK3, and CLK4. A set signal Set is input to the set terminal Set. A reset signal Reset is input to the reset terminal Reset. The scanning signals G generated in other stages are used as the set signal Set and the reset signal Reset. In the illustrated example, the n-th stage SR(n) uses a scanning signal G(n−2) generated two stages earlier as the set signal Set, and a scanning signal G(n+3) generated three stages later as the reset signal Reset.

A first reference voltage signal Vs1 is input to the first reference voltage terminal Vs1. In this specification, being electrically connected to the first reference voltage terminal Vs1 may be expressed as “being electrically connected to a first reference voltage source”, and the first reference voltage signal Vs1 may be expressed as a “potential Vs1 of the first reference voltage source”. A second reference voltage signal Vs2 is input to the second reference voltage terminal Vs2. In this specification, being electrically connected to the second reference voltage terminal Vs2 may be expressed as “being electrically connected to a second reference voltage source”, and the second reference voltage signal Vs2 may be expressed as a “potential Vs2 of the second reference voltage source”. The charge supply terminal Vd is electrically connected to a charge supply source, which will be described below. In this specification, a potential of the charge supply source may be expressed as Vd.

The output terminal G outputs a scanning signal G. The output scanning signal G is supplied to a corresponding scanning signal line GB.

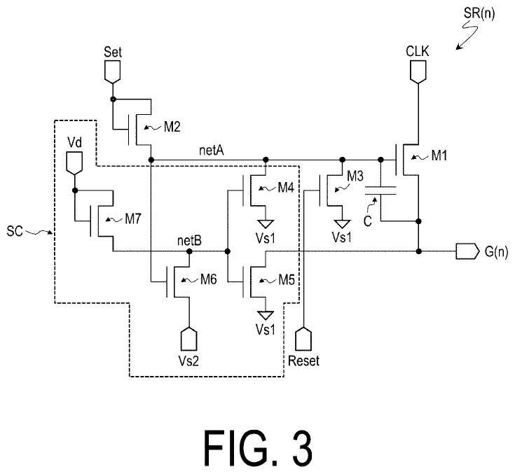

Next, a specific circuit configuration of each stage of the shift register circuit SR will be described with reference to FIG. 3. FIG. 3 is a circuit diagram illustrating a configuration example of the n-th stage SR(n). As illustrated in FIG. 3, each stage of the shift register circuit SR includes a 1st transistor M1, a 2nd transistor M2, a 3rd transistor M3, and a capacitor C.

The 1st transistor M1, the 2nd transistor M2, the 3rd transistor M3, and the capacitor C are electrically connected at a common node netA. This node netA will be referred to as a “first internal node” below.

A gate of the 1st transistor M1 is electrically connected to the first internal node netA. A drain of the 1st transistor M1 is electrically connected to the clock terminal CLK. A source of the 1st transistor M1 is electrically connected to the output terminal G. The 1st transistor M1 has a function of outputting the voltage of the clock signal CLK to the output terminal G.

A gate and a drain of the 2nd transistor M2 are diode-connected and electrically connected to the set terminal Set. A source of the 2nd transistor M2 is electrically connected to the first internal node netA. The 2nd transistor M2 has a function of raising a potential of the first internal node netA.

A gate of the 3rd transistor M3 is electrically connected to the reset terminal Reset. A drain of the 3rd transistor M3 is electrically connected to the first internal node netA. A source of the 3rd transistor M3 is electrically connected to the first reference voltage terminal Vs1 (i.e., to the first reference voltage source). The 3rd transistor M3 has a function of lowering the potential of the first internal node netA.

One end of the capacitor C is electrically connected to the first internal node netA. The other end of the capacitor C is electrically connected to the output terminal G. The capacitor C is a so-called bootstrap capacitor that holds the potential of the first internal node netA that rises when the 2nd transistor M2 is in an on state.

Each stage of the shift register circuit SR further includes a stabilization circuit SC. The stabilization circuit SC is electrically connected to the first internal node netA and the output terminal G, and suppresses fluctuations in the potentials of the first internal node netA and the output terminal G during a non-select period. That is, the stabilization circuit SC is provided to more reliably maintain the potentials of the first internal node netA and the output terminal G at a low level during the non-select period.

In the example illustrated in FIG. 3, the stabilization circuit SC includes a 4th transistor M4, a 5th transistor M5, a 6th transistor M6, and a 7th transistor M7. The 4th transistor M4, the 5th transistor M5, the 6th transistor M6, and the 7th transistor M7 are electrically connected by a common node netB. This node netB will be referred to as a “second internal node” below.

A gate of the 4th transistor M4 is electrically connected to the second internal node netB. A drain of the 4th transistor M4 is electrically connected to the first internal node netA. A source of the 4th transistor M4 is electrically connected to the first reference voltage terminal Vs1 (i.e., to the first reference voltage source). The 4th transistor M4 has a function of maintaining the potential of the first internal node netA at a low level during the non-select period.

A gate of the 5th transistor M5 is electrically connected to the second internal node netB. A drain of the 5th transistor M5 is electrically connected to the output terminal G. A source of the 5th transistor M5 is electrically connected to the first reference voltage terminal Vs1 (i.e., to the first reference voltage source). The 5th transistor M5 has a function of maintaining a potential of the output terminal G at a low level during the non-select period.

When a potential applied to the source of the 4th transistor M4 is referred to as a “first reference potential” and a potential applied to the source of the 5th transistor M5 is referred to as a “second reference potential”, in the example illustrated in FIG. 3, the source of the 4th transistor M4 and the source of the 5th transistor M5 are both electrically connected to the first reference voltage source, and thus the first reference potential and the second reference potential are the same potential.

A gate of the 6th transistor M6 is electrically connected to the first internal node netA. A drain of the 6th transistor M6 is electrically connected to the second internal node netB. A source of the 6th transistor M6 is electrically connected to the second reference voltage terminal Vs2 (i.e., to the second reference voltage source). The 6th transistor M6 has a function of lowering a potential of the second internal node netB.

A gate and a drain of the 7th transistor M7 are diode-connected and are electrically connected to a charge supply source for supplying charge to the second internal node netB via the charge supply terminal Vd. A source of the 7th transistor M7 is electrically connected to the second internal node netB. The 7th transistor M7 has a function of raising the potential of the second internal node netB.

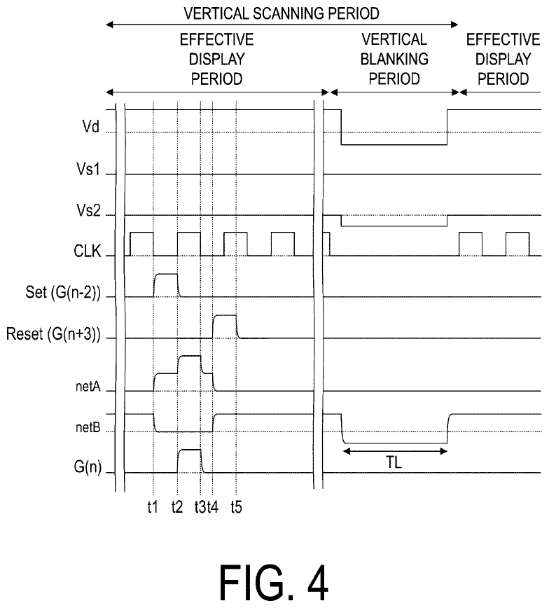

An operation of the shift register circuit SR will be described with reference to FIG. 4. FIG. 4 is an example of a timing chart illustrating the operation of the shift register circuit SR. Here, a “frame” refers to a period during which one image is displayed in the display region AA and is sometimes referred to as a “vertical scanning period”. The reciprocal of the vertical scanning period may be referred to as a vertical frequency, and for example, in the case of 120 Hz driving, 120 images are displayed per second, which may be expressed as 120 fps (120 frames/sec). A frame has a beginning and an end, and does not merely represent a length of time. The timing of the end of a frame is the same as the timing of the beginning of the next frame. A length of time of a frame is referred to as one frame period or one vertical scanning period (1V). A period from when any pixel row (scanning signal line GB) is selected in a frame to when that pixel row (scanning signal line GB) is selected in the next frame corresponds to one frame period (one vertical scanning period). In addition, in a frame, a period from when a pixel row is selected to when the next pixel row is selected is referred to as one horizontal scan period (1H). The vertical scanning period includes an “effective display period”, which is a period from when the first pixel row is selected to when writing of the last pixel row is completed, and a “vertical blanking period”.

At time t1, the set signal Set changes from a low level to a high level. In the following, a change of a signal from a low level to a high level is referred to as “rising”, and a change of a signal from a high level to a low level is referred to as “falling”. Here, the set signal Set is the scanning signal G(n−2) output from the second stage earlier. When the set signal Set rises, the 2nd transistor M2 turns on, and charging (pre-charging) of the capacitor C starts. As a result, the potential of the first internal node netA changes to a precharge voltage. The precharge voltage is a voltage obtained by subtracting a threshold voltage (Vth) of the 2nd transistor M2 from a high-level voltage of the set signal Set. This turns the 1st transistor M1 on. A period from time t1 to time t2 is referred to as a “set period”. During the set period, the clock signal CLK is at a low level, so a signal level output from the 1st transistor M1 is at a low level. That is, the scanning signal G(n) remains unchanged at a low level.

At time t2, the clock signal CLK rises. When the clock signal CLK rises and the potential of the first internal node netA rises, the 2nd transistor M2 turns off, regardless of a voltage level of the set signal Set. This is because a source potential of the 2nd transistor M2 rises and a gate potential becomes relatively low. In the example illustrated in FIG. 4, the set signal Set falls, turning the 2nd transistor M2 off. Further, the reset signal Reset remains at a low level, so the 3rd transistor M3 remains in an off state. As a result, the first internal node netA is in a floating state. At time t2, when the clock signal CLK rises, the charge stored in the capacitor C holds the voltage applied to the capacitor C, that is, a potential difference between the first internal node netA and the output terminal G(n). Therefore, when a potential of the drain of the 1st transistor M1 rises, the potential of the first internal node netA also rises to the input voltage or more. This is the bootstrap of the first internal node netA. By bootstrapping, the potential of the first internal node netA rises to a level even higher than a high level of the clock signal CLK. As a result, the 1st transistor M1 is maintained in the on state, and the signal level output from the 1st transistor M1 becomes at a high level. A period from time t2 to time t3 is referred to as a “bootstrap period”. During the bootstrap period, a high-level scanning signal G(n) is output. A period consisting of the bootstrap period and the set period corresponds to a charging period of the capacitor C.

At time t3, the clock signal CLK falls. At this time, the 1st transistor M1 remains in the on state. The potential of the drain of the 1st transistor M1 drops, and accordingly, the potential of the output terminal G(n) also drops. In addition, as the potential of the output terminal G(n) drops, the potential of the first internal node netA also drops to the level during the set period. A period from time t3 to time t4 is referred to as a “bootstrap release period”.

At time t4, the reset signal Reset rises, turning the 3rd transistor M3 on. Here, the reset signal Reset is the scanning signal G(n+3) output from the third stage later. The charge held in the capacitor C is discharged, and the potential of the first internal node netA drops to a low level and is reset. A period from time t4 to time t5 when the reset signal Reset falls is referred to as a “reset period”.

During the effective display period, during which the first internal node netA is at a low level and the second internal node netB is at a high level (a period before time t1 including time t1 and a period after time t4 including time t4), the 4th transistor M4 and the 5th transistor M5 are in the on state. Thus, the potentials of the first internal node netA and the output terminal G(n) are pulled to the potential Vs1 of the first reference voltage source, so that the potentials of the first internal node netA and the output terminal G(n) can be more reliably maintained at a low level during the non-select period.

In the present embodiment, the potential Vs2 of the second reference voltage source is practically the same as the potential Vs1 of the first reference voltage source during the effective display period, and is lower than the potential Vs1 of the first reference voltage source during at least part of the vertical blanking period (part of the vertical blanking period in the example illustrated in FIG. 4). The potential Vd of the charge supply source is lower than the potential Vs1 of the first reference voltage source during at least part of the vertical blanking period (part of the vertical blanking period in the example illustrated in FIG. 4). Therefore, during at least part of the vertical blanking period (part of the vertical blanking period in the example illustrated in FIG. 4), the potential of the second internal node netB becomes lower than the potential of the first internal node netA, the potential of the output terminal G(n), the first reference potential (here, the potential Vs1 of the first reference voltage source), and the second reference potential (here, the potential Vs1 of the first reference voltage source). Consequently, during at least part of the vertical blanking period, the 4th transistor M4 and the 5th transistor M5, which are stabilization elements, are subjected to a load in an opposite direction to that during other periods. As a result, an effect of the load on the stabilization elements during the other periods is offset by the load in the opposite direction during at least part of the vertical blanking period, suppressing deterioration of characteristics of the stabilization elements.

Note that, while FIG. 4 illustrates an example in which the potential of the second internal node netB is lower than the potential of the first internal node netA and the like during part of the vertical blanking period, the potential of the second internal node netB may be lower than the potential of the first internal node netA and the like during an entire vertical blanking period. A length of the period (period TL in FIG. 4) during which the potential of the second internal node netB is lower than the potential of the first internal node netA, the potential of the output terminal G(n), the first reference potential, and the second reference potential is not limited to a particular length, but from the viewpoint of sufficiently suppressing the deterioration of the characteristics of the stabilization elements, the length of the period TL is preferably set such that a load equivalent to the load applied during the effective display period is applied to the stabilization elements in the opposite direction. For example, when the load applied to the element is expressed by a product of V (applied voltage) and T (application time), that is, V×T, and VH (positive applied voltage) is applied for TH (application time) during the effective display period, it is preferable to apply VL (negative applied voltage) for TL (application time) during the vertical blanking period so that the relationship of VH×TH=VL×TL is satisfied. When it is difficult to set sufficient VL and TL due to constraints such as ensuring the effective display period and power supply, the effect of suppressing the deterioration of the characteristics of the stabilization elements can be maximized by setting VL and TL as large as possible under such constraints.

While FIG. 4 illustrates an example in which the stabilization circuit SC includes both the 4th transistor M4 and the 5th transistor M5, the stabilization circuit SC only need to include at least one of the 4th transistor M4 and the 5th transistor M5. That is, either the 4th transistor M4 or the 5th transistor M5 may be omitted.

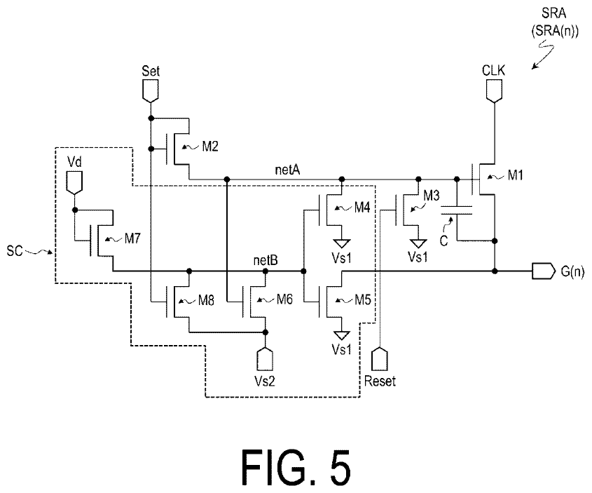

FIG. 5 illustrates another example of a shift register circuit. A shift register circuit SRA illustrated in FIG. 5 differs from the shift register circuit SR illustrated in FIG. 3 in that a stabilization circuit SC of each stage (an n-th stage SRA(n) is illustrated as an example in FIG. 5) includes an 8th transistor M8.

A gate of the 8th transistor M8 is electrically connected to a set terminal Set. A drain of the 8th transistor M8 is electrically connected to a second internal node netB. A source of the 8th transistor M8 is electrically connected to a second reference voltage terminal Vs2 (i.e., to a second reference voltage source). The 8th transistor M8 turns on in response to rising of the set signal Set, and has a function of lowering a potential of the second internal node netB. A timing chart for illustrating an operation of the shift register circuit SRA may be the same as the timing chart illustrated in FIG. 4, for example, and thus, the illustration thereof is omitted here.

In the shift register circuit SRA illustrated in FIG. 5, a stabilization circuit SC includes the 8th transistor M8, which more reliably lowers the second internal node netB, further improving reliability.

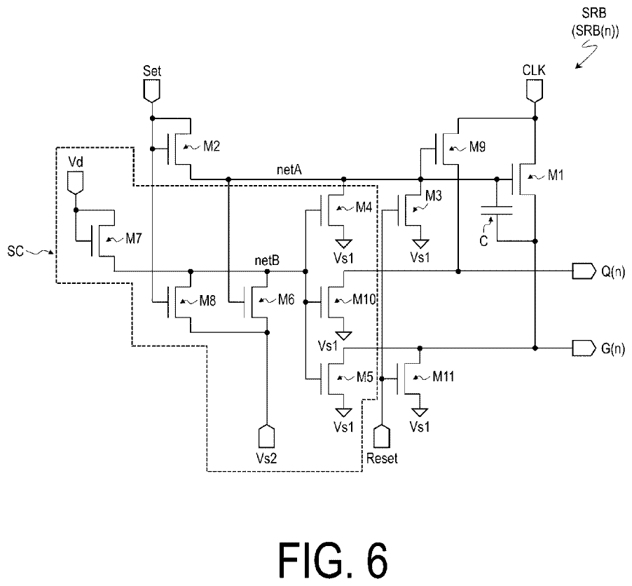

FIG. 6 illustrates still another example of a shift register circuit. A shift register circuit SRB illustrated in FIG. 6 differs from the shift register circuit SRA illustrated in FIG. 5 in that each stage (an n-th stage SRB(n) is illustrated as an example in FIG. 6) further includes an output terminal Q and a 9th transistor M9.

The output terminal Q outputs a signal Q, which drives other stages at the same timing as a scanning signal G is output from an output terminal G. In FIG. 6, the signal output from the output terminal Q of the n-th stage SRB(n) is represented as Q(n). The signal Q is input to other stages as a set signal Set or a reset signal Reset. Here, the n-th stage SRB(n) uses a signal Q(n−2) generated two stages earlier as the set signal Set, and a signal Q(n+3) generated three stages after as the reset signal Reset. In the following, the output terminal G may be referred to as a “first output terminal”, and the output terminal Q may be referred to as a “second output terminal”.

A gate of the 9th transistor M9 is electrically connected to a first internal node netA. A drain of the 9th transistor M9 is electrically connected to a clock terminal CLK. A source of the 9th transistor M9 is electrically connected to the second output terminal Q. The 9th transistor M9 has a function of outputting the voltage of a clock signal CLK to the second output terminal Q.

The shift register circuit SRB illustrated in FIG. 6 also differs from the shift register circuit SRA illustrated in FIG. 5 in that each stage includes a 10th transistor M10 and an 11th transistor M11.

A gate of the 11th transistor M11 is electrically connected to a reset terminal Reset. A drain of the 11th transistor M11 is electrically connected to the first output terminal G. A source of the 11th transistor M11 is electrically connected to a first reference voltage terminal Vs1 (i.e., to a first reference voltage source). The 11th transistor M11 has a function of lowering a potential of the first output terminal G.

Note that while an example in which the gate of the 11th transistor M11 is connected to the reset terminal Reset, the gate of the 11th transistor M11 does not necessarily have to be connected to the reset terminal Reset. The gate of the 11th transistor M11 only needs to be supplied with a signal output from another stage that becomes at a high level during a bootstrap release period or a reset period. For example, the gate of the 11th transistor M11 only needs to be connected to the first output terminal G or the second output terminal Q of a stage later than that stage and to be supplied with the scanning signal G or the signal Q that becomes at a high level during the bootstrap release period or the reset period.

A gate of the 10th transistor M10 is electrically connected to a second internal node netB. A drain of the 10th transistor M10 is electrically connected to the second output terminal Q. A source of the 10th transistor M10 is electrically connected to the first reference voltage terminal Vs1 (i.e., to the first reference voltage source). The 10th transistor M10 has a function of maintaining a potential of the second output terminal Q at a low level during a non-select period, and is included in a stabilization circuit SC.

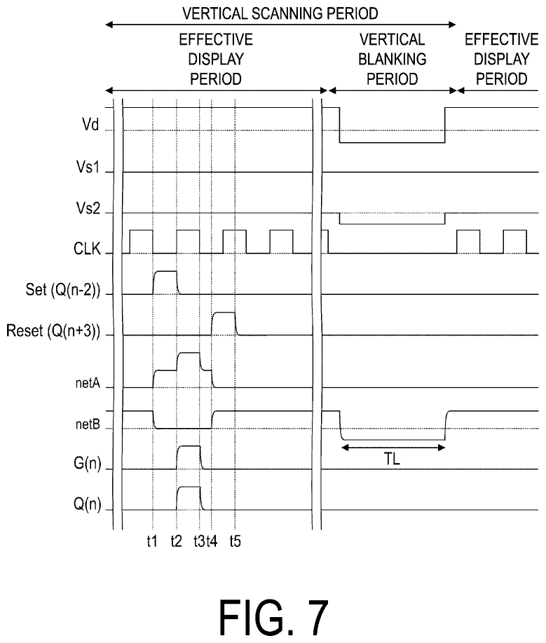

FIG. 7 is an example of a timing chart illustrating an operation of the shift register circuit SRB. As illustrated in FIG. 7, in the shift register circuit SRB, the signal Q, which drives other stages, is output from the second output terminal Q at the same timing as the scanning signal G is output from the first output terminal G.

As described above, in the shift register circuit SRB, the second output terminal Q, which outputs the signal Q, which drives the other stages, is provided separately from the first output terminal G, which outputs the scanning signal G. Capacitance connected to the second output terminal Q is smaller than capacitance connected to the first output terminal G electrically connected to a corresponding scanning signal line GB. Therefore, by providing the second output terminal Q separately from the first output terminal G, a gate drive circuit 120 can be driven at a higher speed.

In the shift register circuit SRB, during an effective display period, during which the first internal node netA is at a low level and the second internal node netB is at a high level (a period before time t1 including time t1 and a period after time t4 including time t4), the 10th transistor M10 is in an on state. As a result, the potential of the second output terminal Q is pulled to a potential Vs1 of the first reference voltage source. Therefore, during the non-select period, the potential of the second output terminal Q can be more reliably maintained at a low level. Further, in the shift register circuit SRB, the 11th transistor M11 is provided, and thus the potential of the first output terminal G can be more reliably lowered to a low level. A signal that becomes at a high level during the bootstrap release period or the reset period is supplied to the gate of the 11th transistor M11, so that deterioration of characteristics of the 11th transistor M11 is suppressed during the non-select period. Consequently, the function of the 11th transistor M11 to lower the potential of the first output terminal G can be favorably maintained.

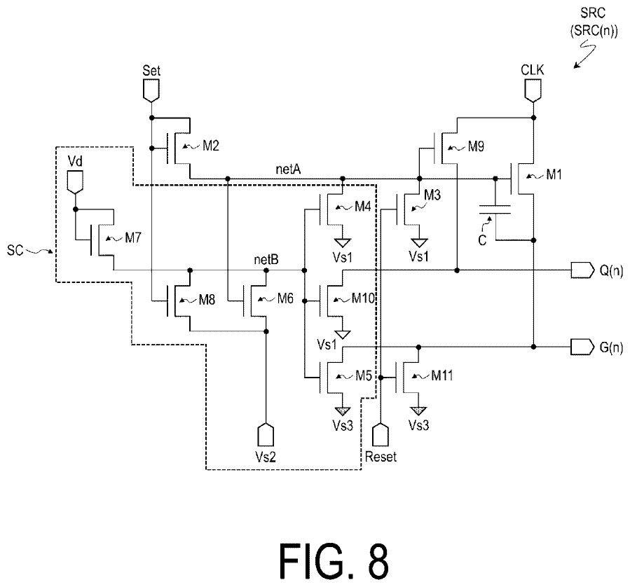

FIG. 8 illustrates yet another example of a shift register circuit. A shift register circuit SRC illustrated in FIG. 8 differs from the shift register circuit SRB illustrated in FIG. 6 in that a source of a 5th transistor M5 and a source of an 11th transistor M11 included in each stage (an n-th stage SRC(n) is illustrated as an example in FIG. 8) are electrically connected to a third reference voltage terminal Vs3 (i.e., to a third reference voltage source). A potential Vs3 of the third reference voltage source is higher than a potential Vs1 of a first reference voltage source. Therefore, in the shift register circuit SRC, a first reference potential applied to a source of a 4th transistor M4 and a second reference potential applied to the source of the 5th transistor M5 are different potentials.

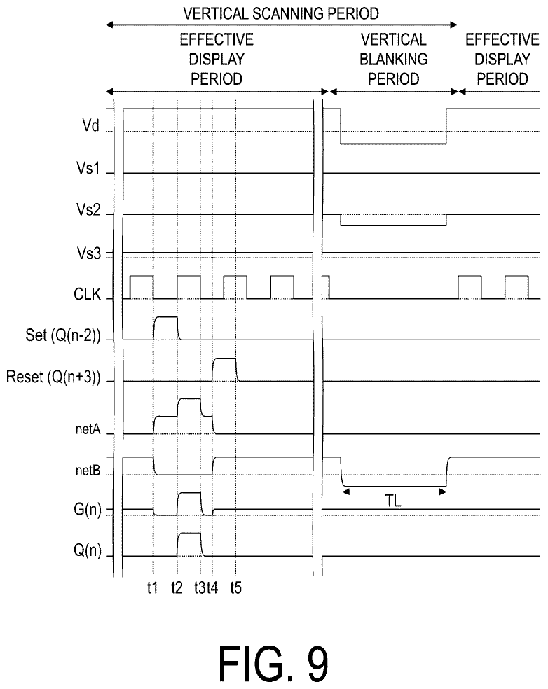

FIG. 9 is an example of a timing chart illustrating an operation of the shift register circuit SRC. As illustrated in FIG. 9, in the shift register circuit SRC, a low level of a scanning signal G during a set period (a period from time t1 to time t2) and a bootstrap release period (a period from time t3 to time t4) is even lower than a low level of a scanning signal G during other periods (before time t1 including time t1 and after time t4 including time t4). That is, the scanning signal G undershoots before and after a bootstrap period (a period from time t2 to time t3). By causing the scanning signal G to undershoot during the bootstrap release period, the scanning signal G can be caused to fall at a higher speed. This enables higher speed driving of the display device and improvement of display quality.

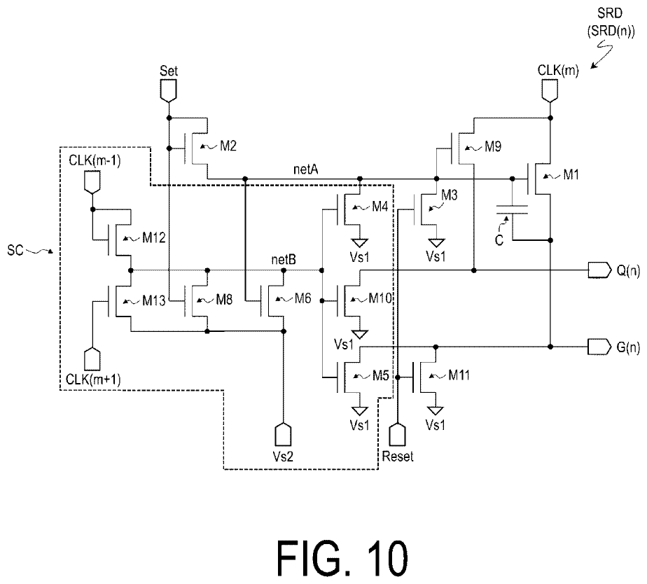

FIG. 10 illustrates a further example of a shift register circuit. Each stage of the shift register circuit SRB illustrated in FIG. 6 includes the single clock terminal CLK to which the clock signal is input. In contrast, each stage of a shift register circuit SRD illustrated in FIG. 10 (an n-th stage SRD(n) is illustrated as an example in FIG. 10) includes three clock terminals CLK(m), CLK(m−1), and CLK(m+1) to which clock signals are input, respectively.

In the following, for convenience of description, the clock terminals CLK(m), CLK(m−1), and CLK(m+1) are referred to as a “first clock terminal”, a “second clock terminal”, and a “third clock terminal”, respectively, and the clock signals input to the clock terminals CLK(m), CLK(m−1), and CLK(m+1) are referred to as a “first clock signal”, a “second clock signal”, and a “third clock signal”, respectively.

The first clock terminal CLK(m) corresponds to the clock terminal CLK of the shift register circuit SRB illustrated in FIG. 6, and is electrically connected to a drain of a 1st transistor M1 and a drain of a 9th transistor M9. Here, the first clock signal input to the first clock terminal CLK(m) is an m-th phase clock signal.

The second clock signal input to the second clock terminal CLK(m−1) is a clock signal of an (m−1)-th phase, which has a phase shifted from the phase of the first clock signal.

The third clock signal input to the third clock terminal CLK(m+1) is a clock signal of an (m+1)-th phase, which has a phase opposite to that of the second clock signal.

The shift register circuit SRD also differs from the shift register circuit SRB illustrated in FIG. 6 in that a stabilization circuit SC of each stage includes a 12th transistor M12 and a 13th transistor M13 instead of the 7th transistor M7.

A gate and a drain of the 12th transistor M12 are diode-connected and electrically connected to the second clock terminal CLK(m−1). A source of the 12th transistor M12 is electrically connected to a second internal node netB. The 12th transistor M12 has a function of raising a potential of the second internal node netB.

A gate of the 13th transistor M13 is electrically connected to the third clock terminal CLK(m+1). A drain of the 13th transistor M13 is electrically connected to the second internal node netB. A source of the 13th transistor M13 is electrically connected to a second reference voltage terminal Vs2 (i.e., to a second reference voltage source). The 13th transistor M13 has a function of lowering the potential of the second internal node netB.

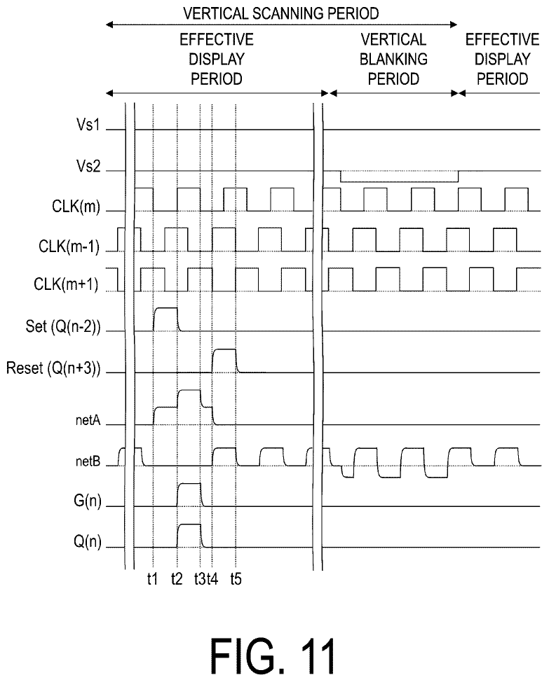

FIG. 11 is an example of a timing chart illustrating an operation of the shift register circuit SRD. As illustrated in FIG. 11, in the shift register circuit SRD, the second internal node netB rises and falls periodically during a non-select period. That is, the second internal node netB is alternated. This reduces a load on stabilization elements during the non-select period, thereby further suppressing deterioration of characteristics of the stabilization elements and further improving reliability.

Note that while an example in which the second clock signal has the phase shifted from the phase of the first clock signal is described here, the second clock signal may have a phase identical to the phase of the first clock signal. While an example in which the third clock signal has the opposite phase to the phase of the second clock signal is described here, the third clock signal does not necessarily have to have the opposite phase to the phase of the second clock signal, as long as the third clock signal has a phase shifted from the phase of the second clock signal. When focusing on a select period of a certain stage, the second clock signal is a signal that rises at the same timing as or earlier than rising of the first clock signal, and the third clock signal is a signal that rises at a timing later than the rising of the first clock signal.

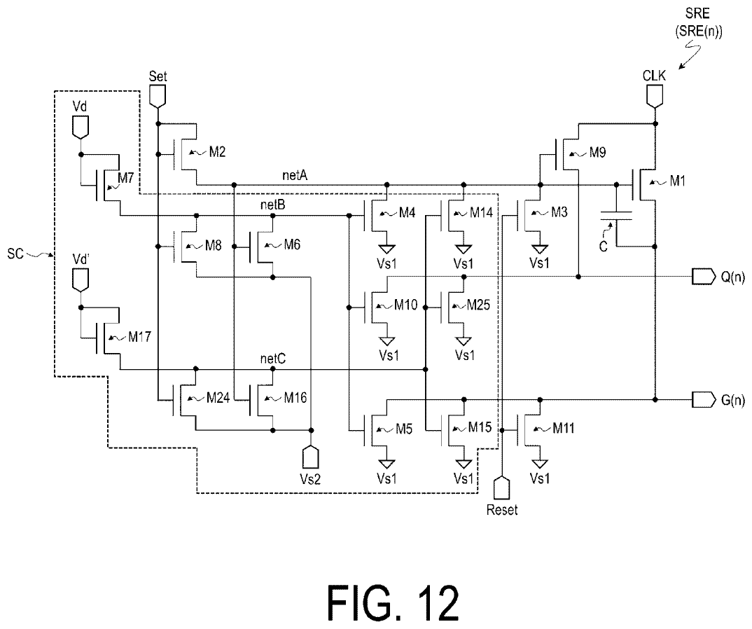

FIG. 12 illustrates a still further example of a shift register circuit. A shift register circuit SRE illustrated in FIG. 12 differs from the shift register circuit SRB illustrated in FIG. 6 in that a stabilization circuit SC of each stage (an n-th stage SRE(n) is illustrated as an example in FIG. 12) includes a 14th transistor M14, a 15th transistor M15, a 16th transistor M16, a 17th transistor M17, a 24th transistor M24, and a 25th transistor M25.

The 14th transistor M14, the 15th transistor M15, the 16th transistor M16, the 17th transistor M17, the 24th transistor M24, and the 25th transistor M25 described above are electrically connected by a common node netC. This node netC will be referred to as a “third internal node” below.

A gate of the 14th transistor M14 is electrically connected to the third internal node netC. A drain of the 14th transistor M14 is electrically connected to a first internal node netA. A source of the 14th transistor M14 is electrically connected to a first reference voltage terminal Vs1 (i.e., to a first reference voltage source). The 14th transistor M14 has a function of maintaining a potential of the first internal node netA at a low level during a non-select period.

A gate of the 15th transistor M15 is electrically connected to the third internal node netC. A drain of the 15th transistor M15 is electrically connected to a first output terminal G. A source of the 15th transistor M15 is electrically connected to the first reference voltage terminal Vs1 (i.e., to the first reference voltage source). The 15th transistor M15 has a function of maintaining a potential of the first output terminal G at a low level during the non-select period.

When a potential applied to the source of the 14th transistor M14 is referred to as a “first reference potential” and a potential applied to the source of the 15th transistor M15 is referred to as a “second reference potential”, in the example illustrated in FIG. 12, the source of the 14th transistor M14 and the source of the 15th transistor M15 are both electrically connected to the first reference voltage source, and thus the first reference potential and the second reference potential are the same potential.

A gate of the 16th transistor M16 is electrically connected to the first internal node netA. A drain of the 16th transistor M16 is electrically connected to the third internal node netC. A source of the 16th transistor M16 is electrically connected to a second reference voltage terminal Vs2 (i.e., to a second reference voltage source). The 16th transistor M16 has a function of lowering a potential of the third internal node netC.

A gate and a drain of the 17th transistor M17 are diode-connected and electrically connected to a charge supply source for supplying charge to the third internal node netC via a charge supply terminal Vd′. A source of the 17th transistor M17 is electrically connected to the third internal node netC. The 17th transistor M17 has a function of raising the potential of the third internal node netC. In the following description, a charge supply source for supplying charge to a second internal node netB may be referred to as a “first charge supply source”, and the charge supply source for supplying charge to the third internal node netC may be referred to as a “second charge supply source”.

A gate of the 24th transistor M24 is electrically connected to a set terminal Set. A drain of the 24th transistor M24 is electrically connected to the third internal node netC. A source of the 24th transistor M24 is electrically connected to the second reference voltage terminal Vs2 (i.e., to the second reference voltage source). The 24th transistor M24 turns on in response to rising of the set signal Set, and has a function of lowering the potential of the third internal node netC.

A gate of the 25th transistor M25 is electrically connected to the third internal node netC. A drain of the 25th transistor M25 is electrically connected to a second output terminal Q. A source of the 25th transistor M25 is electrically connected to the first reference voltage terminal Vs1 (i.e., to the first reference voltage source). The 25th transistor M25 has a function of maintaining a potential of the second output terminal Q at a low level during the non-select period.

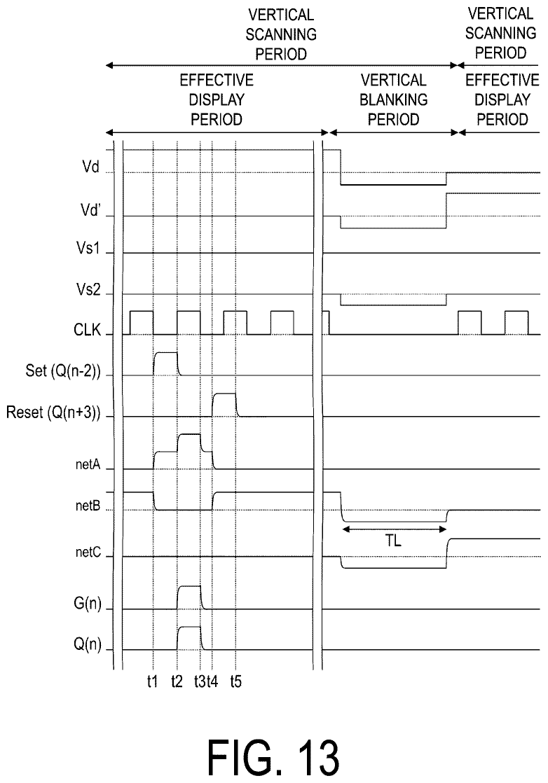

FIG. 13 is an example of a timing chart illustrating an operation of the shift register circuit SRE. As illustrated in FIG. 13, during an effective display period of one of two consecutive vertical scanning periods, the potential Vd of the first charge supply source is at a high level, and the potential Vd′ of the second charge supply source is at a low level (i.e., the potential Vd of the first charge supply source is higher than the potential Vd′ of the second charge supply source). During an effective display period of another of the two consecutive vertical scanning periods, the potential Vd′ of the second charge supply source is at a high level, and the potential Vd of the first charge supply source is at a low level (i.e., the potential Vd′ of the second charge supply source is higher than the potential Vd of the first charge supply source). In other words, in the shift register circuit SRE, a vertical scanning period during which the potential Vd of the first charge supply source is at a high level and the potential Vd′ of the second charge supply source is at a low level during the effective display period and a vertical scanning period during which the potential Vd′ of the second charge supply source is at a high level and the potential Vd of the first charge supply source is at a low level during the effective display period are alternately repeated.

Therefore, during the vertical scanning period during which the potential Vd of the first charge supply source is at a high level during the effective display period, the 4th transistor M4, the 5th transistor M5, the 6th transistor M6, the 7th transistor M7, the 8th transistor M8, and the 10th transistor M10 electrically connected to the second internal node netB function as a stabilization circuit. During the vertical scanning period during which the potential Vd′ of the second charge supply source is at a high level during the effective display period, the 14th transistor M14, the 15th transistor M15, the 16th transistor M16, the 17th transistor M17, the 24th transistor M24, and the 25th transistor M25 electrically connected to the third internal node netC function as a stabilization circuit.

The potential Vd′ of the second charge supply source is lower than a potential Vs1 of the first reference voltage source during at least part of a vertical blanking period (part of the vertical blanking period in the example illustrated in FIG. 13). Therefore, during at least part of the vertical blanking period (part of the vertical blanking period in the example illustrated in FIG. 13), the potential of the third internal node netC becomes lower than the potential of the first internal node netA, the potential of the output terminal G(n), the first reference potential (here, the potential Vs1 of the first reference voltage source), and the second reference potential (here, the potential Vs1 of the first reference voltage source). This suppresses deterioration of characteristics of the 14th transistor M14 and the 15th transistor M15, which are stabilization elements controlled by the third internal node netC, for the same reasons as the 4th transistor M4 and the 5th transistor M5, which are the stabilization elements controlled by the second internal node netB.

As already described, in the shift register circuit SRE illustrated in FIG. 12, the stabilization circuit SC is divided into two systems, and one system and another system function alternately, which further suppresses the deterioration of the characteristics of the stabilization elements and further improves reliability.

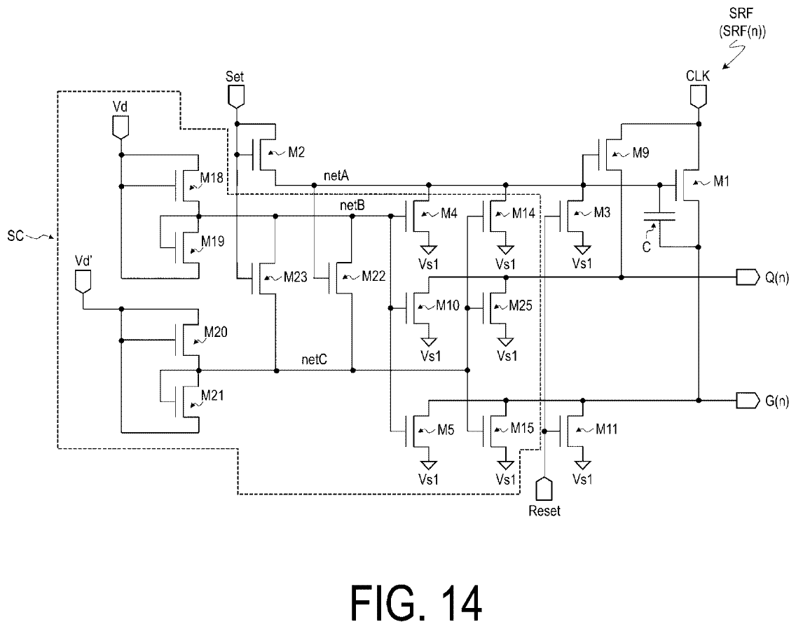

FIG. 14 illustrates a yet further example of a shift register circuit. A shift register circuit SRF illustrated in FIG. 14 differs from the shift register circuit SRE illustrated in FIG. 12 in that a stabilization circuit SC of each stage (an n-th stage SRF(n) is illustrated as an example in FIG. 14) includes an 18th transistor M18, a 19th transistor M19, a 20th transistor M20, a 21st transistor M21, a 22nd transistor M22, and a 23rd transistor M23 instead of the 6th transistor M6, the 7th transistor M7, the 8th transistor M8, the 16th transistor M16, and the 17th transistor M17.

A gate and a drain of the 18th transistor M18 are diode-connected and electrically connected to a first charge supply source for supplying charge to a second internal node netB via a charge supply terminal Vd. A source of the 18th transistor M18 is electrically connected to the second internal node netB. The 18th transistor M18 has a function of raising a potential of the second internal node netB.

A gate and a drain of the 19th transistor M19 are diode-connected and electrically connected to the source of the 18th transistor M18 (i.e., electrically connected to the second internal node netB). A source of the 19th transistor M19 is electrically connected to the first charge supply source via the charge supply terminal Vd. The 19th transistor M19 has a function of lowering the potential of the second internal node netB during a period during which a potential Vd of the first charge supply source is lower than the potential of the second internal node netB.

A gate and a drain of the 20th transistor M20 are diode-connected and electrically connected to a second charge supply source for supplying charge to a third internal node netC via a charge supply terminal Vd′. A source of the 20th transistor M20 is electrically connected to the third internal node netC. The 20th transistor M20 has a function of raising a potential of the third internal node netC.

A gate and a drain of the 21st transistor M21 are diode-connected and electrically connected to the source of the 20th transistor M20 (i.e., electrically connected to the third internal node netC). A source of the 21st transistor M21 is electrically connected to the second charge supply source via the charge supply terminal Vd′. The 21st transistor M21 has a function of lowering the potential of the third internal node netC during a period during which a potential Vd′ of the second charge supply source is lower than the potential of the third internal node netC.

A gate of the 22nd transistor M22 is electrically connected to a first internal node netA. A drain of the 22nd transistor M22 is electrically connected to the second internal node netB. A source of the 22nd transistor M22 is electrically connected to the third internal node netC. The 22nd transistor M22 turns on in response to rising of the first internal node netA, and electrically connects the second internal node netB and the third internal node netC.

A gate of the 23rd transistor M23 is electrically connected to a set terminal Set. A drain of the 23rd transistor M23 is electrically connected to the second internal node netB. A source of the 23rd transistor M23 is electrically connected to the third internal node netC. The 23rd transistor M23 turns on in response to rising of the set signal Set, and electrically connects the second internal node netB and the third internal node netC.

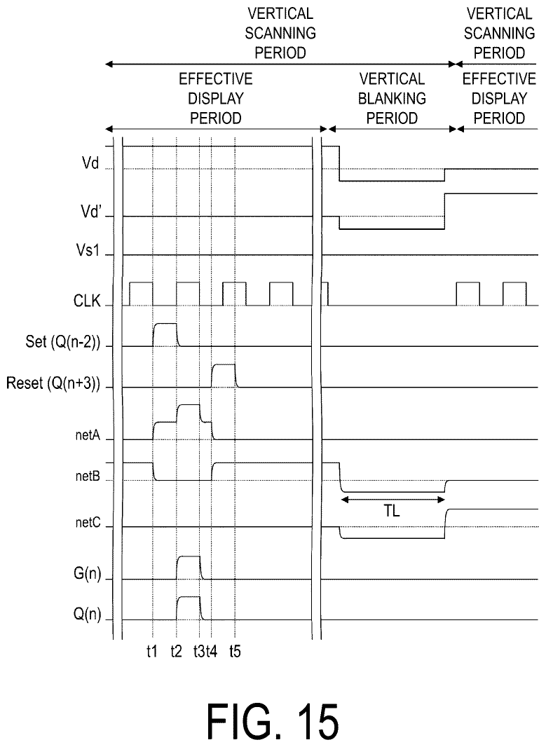

FIG. 15 is an example of a timing chart illustrating an operation of the shift register circuit SRF. As illustrated in FIG. 15, during an effective display period of one of two consecutive vertical scanning periods, the potential Vd of the first charge supply source is higher than the potential Vd′ of the second charge supply source, and during an effective display period of another of the two consecutive vertical scanning periods, the potential Vd′ of the second charge supply source is higher than the potential Vd of the first charge supply source. A vertical scanning period during which the potential Vd of the first charge supply source is at a high level and the potential Vd′ of the second charge supply source is at a low level during the effective display period and a vertical scanning period during which the potential Vd′ of the second charge supply source is at a high level and the potential Vd of the first charge supply source is at a low level during the effective display period are alternately repeated.

Therefore, during the vertical scanning period during which the potential Vd of the first charge supply source is at a high level during the effective display period, the 4th transistor M4 and the 5th transistor M5 electrically connected to the second internal node netB function as stabilization elements, and during the vertical scanning period during which the potential Vd′ of the second charge supply source is at a high level during the effective display period, the 14th transistor M14 and the 15th transistor M15 electrically connected to the third internal node netC function as stabilization elements.

Thus, in the shift register circuit SRF illustrated in FIG. 14, the stabilization circuit SC is also divided into two systems, and thus, an effect of improving reliability by the two systems can be obtained. In addition, the shift register circuit SRF does not require the second reference voltage signal Vs2, so the number of input signals can be reduced.

Note that, in the shift register circuit SRF illustrated in FIG. 14 as well, the potential Vd of the first charge supply source and the potential Vd′ of the second charge supply source are each lower than a potential Vs1 of the first reference voltage source during at least part of a vertical blanking period. Therefore, during at least part of the vertical blanking period, the potential of the second internal node netB and the potential of the third internal node netC are each lower than a potential of the first internal node netA, a potential of the output terminal G(n), a first reference potential (here, the potential Vs1 of a first reference voltage source), and a second reference potential (here, the potential Vs1 of the first reference voltage source). This suppresses deterioration of characteristics of the 4th transistor M4, the 5th transistor M5, the 14th transistor M14, and the 15th transistor M15, which are the stabilization elements.

### INDUSTRIAL APPLICABILITY

According to the embodiments of the disclosure, a scanning signal line drive circuit can be provided that can suppress deterioration of characteristics of stabilization elements in a stabilization circuit provided in each stage of a shift register circuit. Scanning signal line drive circuits according to the embodiments of the disclosure are suitable for use in display devices such as liquid crystal display devices.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A scanning signal line drive circuit configured to supply scanning signals to multiple scanning signal lines included in a display device, the scanning signal line drive circuit comprising:
a shift register circuit including multiple stages,
wherein each of the multiple stages includes a first clock terminal configured to receive a first clock signal,
a set terminal configured to receive a set signal,
a reset terminal configured to receive a reset signal,
a first output terminal configured to output a scanning signal,
a 1st transistor including a gate electrically connected to a first internal node, and a source and a drain, one of the source and the drain electrically connected to the clock terminal and another of the source and the drain electrically connected to the first output terminal,
a 2nd transistor including a gate electrically connected to the set terminal, and a source and a drain, one of the source and the drain electrically connected to the first internal node,
a 3rd transistor including a gate electrically connected to the reset terminal, and a source and a drain, one of the source and the drain electrically connected to the first internal node and another of the source and the drain electrically connected to a first reference voltage source,
a stabilization circuit electrically connected to the first internal node and the first output terminal, and configured to suppress fluctuations in potentials of the first internal node and the first output terminal during a non-select period,
the stabilization circuit includes at least one of a 4th transistor including a gate electrically connected to a second internal node, and a source and a drain, one of the source and the drain electrically connected to the first internal node, and another of the source and the drain supplied with a first reference potential, and
a 5th transistor including a gate electrically connected to the second internal node, and a source and a drain, one of the source and the drain electrically connected to the first output terminal and another of the source and the drain configured to be supplied with a second reference potential, the second reference potential being identical to or different from the first reference potential, and
during at least part of a vertical blanking period of an effective display period and the vertical blanking period included in a vertical scanning period, a potential of the second internal node is lower than the potential of the first internal node, the potential of the first output terminal, the first reference potential, and the second reference potential.

2. The scanning signal line drive circuit according to claim 1,
wherein the stabilization circuit includes at least the 4th transistor of the 4th transistor and the 5th transistor,
the other of the source and the drain of the 4th transistor is electrically connected to the first reference voltage source,
the stabilization circuit further includes a 6th transistor including a gate electrically connected to the first internal node, and a source and a drain, one of the source and the drain electrically connected to the second internal node and another of the source and the drain electrically connected to a second reference voltage source, and
a potential of the second reference voltage source is practically identical to a potential of the first reference voltage source during the effective display period, and is lower than the potential of the first reference voltage source during the at least part of the vertical blanking period.

3. The scanning signal line drive circuit according to claim 2,
wherein the stabilization circuit further includes a 7th transistor including a source and a drain, one of the source and the drain electrically connected to a first charge supply source configured to supply charge to the second internal node and another of the source and the drain electrically connected to the second internal node, and
a potential of the first charge supply source is lower than the potential of the first reference voltage source during the at least part of the vertical blanking period.

4. The scanning signal line drive circuit according to claim 2,
wherein the stabilization circuit further includes an 8th transistor including a gate electrically connected to the set terminal, and a source and a drain, one of the source and the drain electrically connected to the second internal node and another of the source and the drain electrically connected to the second reference voltage source.

5. The scanning signal line drive circuit according to claim 1,
wherein each of the multiple stages further includes a second output terminal configured to output a signal configured to drive another stage at the same timing as the scanning signal is output from the first output terminal, and
a 9th transistor including a gate electrically connected to the first internal node, and a source and a drain, one of the source and the drain electrically connected to the clock terminal and another of the source and the drain electrically connected to the second output terminal.

6. The scanning signal line drive circuit according to claim 5,
wherein each of the multiple stages further includes a 10th transistor including a gate electrically connected to the second internal node, and a source and a drain, one of the source and the drain electrically connected to the second output terminal and another of the source and the drain electrically connected to the first reference voltage source.

7. The scanning signal line drive circuit according to claim 1,
wherein each of the multiple stages further includes an 11th transistor including a gate configured to be supplied with a signal output from another stage, and a source and a drain, one of the source and the drain electrically connected to the first output terminal and another of the source and the drain electrically connected to the first reference voltage source.

8. The scanning signal line drive circuit according to claim 5,
wherein the stabilization circuit includes at least the 5th transistor of the 4th transistor and the 5th transistor,
each of the multiple stages further includes a 10th transistor including a gate electrically connected to the second internal node, and a source and a drain, one of the source and the drain electrically connected to the second output terminal and another of the source and the drain electrically connected to the first reference voltage source,
the other of the source and the drain of the 5th transistor is electrically connected to a third reference voltage source, and a potential of the third reference voltage source is higher than a potential of the first reference voltage source.

9. The scanning signal line drive circuit according to claim 8,
wherein each of the multiple stages further includes an 11th transistor including a gate configured to be supplied with a signal output from another stage, and a source and a drain, one of the source and the drain electrically connected to the first output terminal and another of the source and the drain electrically connected to the third reference voltage source.

10. The scanning signal line drive circuit according to claim 1,
wherein the stabilization circuit includes both the 4th transistor and the 5th transistor, and
the other of the source and the drain of the 4th transistor and the other of the source and the drain of the 5th transistor are each electrically connected to the first reference voltage source, and the first reference potential is identical to the second reference potential.

11. The scanning signal line drive circuit according to claim 2,
wherein each of the multiple stages further includes a second clock terminal configured to receive a second clock signal having a phase identical to or a phase shifted from a phase of the first clock signal, and
a third clock terminal configured to receive a third clock signal having a phase shifted from the phase of the second clock signal, and
the stabilization circuit further includes a 12th transistor including a gate electrically connected to the second clock terminal and a source and a drain, one of the source and the drain electrically connected to the second internal node, and
a 13th transistor including a gate electrically connected to the third clock terminal, and a source and a drain, one of the source and the drain electrically connected to the second internal node and another of the source and the drain electrically connected to the second reference voltage source.

12. The scanning signal line drive circuit according to claim 3,
wherein the stabilization circuit further includes a 14th transistor including a gate electrically connected to a third internal node, and a source and a drain, one of the source and the drain electrically connected to the first internal node and another of the source and the drain configured to be supplied with the first reference potential,
a 15th transistor including a gate electrically connected to the third internal node, and a source and a drain, one of the source and the drain electrically connected to the first output terminal and another of the source and the drain configured to be supplied with the second reference potential,
a 16th transistor including a gate electrically connected to the first internal node, and a source and a drain, one of the source and the drain electrically connected to the third internal node and another of the source and the drain electrically connected to the second reference voltage source, and
a 17th transistor including a source and a drain, one of the source and the drain electrically connected to a second charge supply source configured to supply charge to the third internal node and another of the source and the drain electrically connected to the third internal node,
a potential of the second charge supply source is lower than the potential of the first reference voltage source during the at least part of the vertical blanking period, and
the potential of the first charge supply source is higher than the potential of the second charge supply source during the effective display period of one of two consecutive vertical scanning periods, and the potential of the second charge supply source is higher than the potential of the first charge supply source during the effective display period of another of the two consecutive vertical scanning periods.

13. The scanning signal line drive circuit according to claim 3,
wherein the stabilization circuit further includes a 14th transistor including a gate electrically connected to a third internal node, and a source and a drain, one of the source and the drain electrically connected to the first internal node and another of the source and the drain configured to be supplied with the first reference potential,
a 15th transistor including a gate electrically connected to the third internal node, and a source and a drain, one of the source and the drain electrically connected to the first output terminal and another of the source and the drain configured to be supplied with the second reference potential,
an 18th transistor including a source and a drain, one of the source and the drain electrically connected to the first charge supply source configured to supply charge to the second internal node and another of the source and the drain electrically connected to the second internal node,
a 19th transistor including a gate, a source, and a drain, the gate and one of the source and the drain electrically connected to the second internal node and another of the source and the drain electrically connected to the first charge supply source,
a 20th transistor including a source and a drain, one of the source and the drain electrically connected to a second charge supply source configured to supply charge to the third internal node and another of the source and the drain electrically connected to the third internal node,
a 21st transistor including a gate, a source, and a drain, the gate and one of the source and the drain electrically connected to the third internal node and another of the source and the drain electrically connected to the second charge supply source,
a 22nd transistor including a gate electrically connected to the first internal node, and a source and a drain, one of the source and the drain electrically connected to the second internal node and another of the source and the drain electrically connected to the third internal node, and
a 23rd transistor including a gate electrically connected to the set terminal, and a source and a drain, one of the source and the drain electrically connected to the second internal node and another of the source and the drain electrically connected to the third internal node,
the potential of the first charge supply source and a potential of the second charge supply source are each lower than the potential of the first reference voltage source during the at least part of the vertical blanking period, and
during the effective display period of one of two consecutive vertical scanning periods, the potential of the first charge supply source is higher than the potential of the second charge supply source, and during the effective display period of another of the two consecutive vertical scanning periods, the potential of the second charge supply source is higher than the potential of the first charge supply source.

14. A display device having multiple pixels arranged in a matrix including multiple pixel rows and multiple pixel columns, the display device comprising:
multiple scanning signal lines, each of the multiple scanning signal lines being associated with one of the multiple pixel rows; and
the scanning signal line drive circuit according to claim 1 configured to supply scanning signals to the multiple scanning signal lines.
